(19) United States
(12) Patent Application Publication
(10) Pub. No.: US 2004/0255224 A1
(43) Pub. Date: Dec. 16, 2004

(54) Semiconductor storage device and evaluation method

(76) Inventor: Tomoaki Yabe, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/641,048

(22) Filed: Aug. 15, 2003

(30) Foreign Application Priority Data
Jun. 11, 2003 (JP) 2003-166852

(51) Int. Cl. G11C 29/00

(52) U.S. Cl. 714/763

(57) ABSTRACT

A semiconductor storage device includes a memory cell array which stores externally inputted normal data, an inspection data generating circuit which generates inspection data corresponding to the normal data, an inspection storing section which stores the inspection data, and a syndrome generating circuit which generates a syndrome signal by detecting bit errors in read data on the basis of the inspection data, the read data being obtained by reading the normal data stored in the memory cell array. Furthermore, the present device includes a syndrome signal processing circuit which corrects the errors in the read data on the basis of the syndrome signal and which generates an internal error address signal representative of addresses of those memory cells in the memory cell array in which the bit errors have occurred.

### CROSS-REFERENCE TO RELATED APPLICATIONS

This application is based upon and claims the benefit of priority from the prior Japanese Patent Application No. 2003-166852, filed Jun. 11, 2003, the entire contents of which are incorporated herein by reference.

### BACKGROUND OF THE INVENTION

1. Field of the Invention

The present invention relates to a semiconductor storage device comprising an ECC (Error Correction Code) circuit and evaluation method.

2. Description of the Related Art

Recent semiconductor storage devices have scaled-down structures. However, with such a scaled-down structure, software errors may occur in memory cells of the semiconductor storage device, which destroy cell data. To solve this problem, various methods have been proposed for using an error correction code technique, to restore destroyed data. For example, KIYOHIRO FURUTANI et al., A Built-In Hamming Code ECC Circuit for DRAM's, IEEE JOURNAL OF SOLID-STATE CIRCUITS, VOL. 24, NO. 1, FEBRUARY 1989, p. 50 to 56 discloses a semiconductor storage device in which an ECC circuit is integrated on the same chip on which a memory cell array is formed so that a user can use the device without being conscious of any error corrections. This semiconductor storage device with the ECC circuit enables the correction of data stored in the memory cells that have become defective during a manufacturing process. This improves the manufacturing yield of semiconductor storage devices.

Even if the ECC circuit is thus used to restore defective memory cells, the processing yield of the memory cell array prior to error correction must be tested in order to monitor and manage the production line. To test the processing yield, an error correction enable signal providing control as to whether or not to carry out error correction is inputted to the semiconductor storage device. Then, it is determined whether the error correction enable signal is high-level (error correction needs to be carried out) or low-level (error correction does not need to be carried out). On the basis of these results, in the former case, it is possible to check whether or not the functions of the memory have any problems including errors to be corrected. In the latter case, it is possible to test the processing yield of the memory cell array of the semiconductor storage device prior to error correction.

Further, as a related technique, Jpn. Pat. Appln. KOKAI Publication No. 2000-149598 proposes a method of accumulating a plurality of test data in the semiconductor storage device and outputting them in a packet form.

However, to test the processing yield of the memory cell array, different operation tests must be conducted according to whether or not error correction needs to be carried out. As a result, two operation tests must be executed. Thus, disadvantageously, much time is required to complete the memory tests, thus increasing test costs. In particular, for system LSIs or the like in which several dozen or more memory macros mounted on the same chip must all be tested, this increased test time is a serious problem.

### BRIEF SUMMARY OF THE INVENTION

According to a first aspect of the present invention, there is provided a semiconductor storage device comprising a memory cell array which stores externally inputted normal data, an inspection data generating circuit which generates inspection data corresponding to the normal data, an inspection storing section which stores the inspection data, and a syndrome generating circuit which generates a syndrome signal by detecting bit errors in read data on the basis of the inspection data, the read data being obtained by reading the normal data stored in the memory cell array. The present device further comprises a syndrome signal processing circuit which corrects the errors in the read data on the basis of the syndrome signal and which generates an internal error address signal representative of addresses of those memory cells in the memory cell array in which the bit errors have occurred.

According to a second aspect of the present invention, there is provided a semiconductor storage device comprising a memory macro having a memory cell array and an error correcting circuit, an input data generating circuit which generates input data to be written in the memory macro, and an error signal generating circuit which compares output data read from the memory macro with the input data generated by the input data generating circuit to generate an error signal indicating whether or not there are any errors in the output data. The present device further comprises an internal error address register which temporarily stores an internal error address signal representative of error addresses of those memory cells in the memory cell array in which bit errors in read data have occurred, the read data being obtained by reading the input data stored in the memory cell array and outputted by the memory macro.

According to a third aspect of the present invention, there is provided an evaluation method for a semiconductor storage device having a memory cell array and an error correcting circuit, the method comprising generating an address used to specify locations in the semiconductor storage device at which input data is stored, temporarily storing the address, inputting the temporarily stored address to the semiconductor storage device, generating the input data to be written in the semiconductor storage device, and writing the input data in the semiconductor storage device. The present evaluation method further comprises reading the input data from the semiconductor storage device, comparing the output data read from the semiconductor storage device with the generating input data to generate an error signal indicating whether or not there are any errors in the output data based on a comparison result of the output data and the input data, temporarily storing the error signal, and temporarily storing an internal error address signal outputted by the semiconductor storage device and representing error addresses of those memory cells in the memory cell array in which bit errors in read data have occurred, the read data being obtained by reading the input data stored in the memory cell array.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of the invention.

FIG. 1 is a circuit block diagram of a semiconductor storage device 100 according to a first embodiment of the present invention;

FIG. 2 is a flow chart representing an evaluation method for the semiconductor storage device shown in FIG. 1;

FIG. 3 is a block diagram of a semiconductor storage device 200 according to a second embodiment of the present invention;

FIG. 4 is a flow chart representing a process in which a BIST circuit 20 writes data in a memory macro 21; and

FIG. 5 is a flow chart representing a process in which the BIST circuit 20 reads data from the memory macro 21.

### DETAILED DESCRIPTION OF THE INVENTION

Embodiments of the present invention will be described below with reference to the drawings.

### FIRST EMBODIMENT

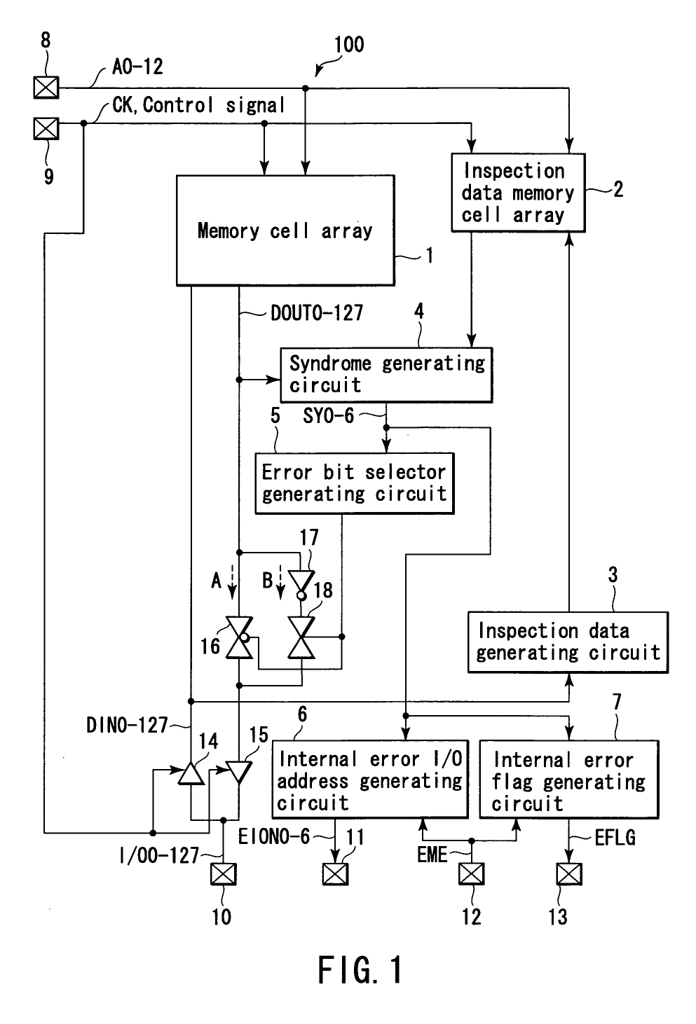

FIG. 1 is a circuit block diagram of a semiconductor storage device 100 according to a first embodiment of the present invention.

The semiconductor storage device 100 comprises a memory cell array 1 used to store write data, and an inspection data memory cell array 2 used to store inspection data required for error correction. The memory cell array 1 has a capacity of, for example, 1M bits (8 k words×128 bits) . The inspection data memory cell array 2 has a capacity of, for example, 72 k bits (8 k words×9 bits). The memory cell array 1 and the inspection data memory cell array 2 are each composed of, for example, an SRAM. However, the present invention is not limited to this aspect.

Further, the semiconductor storage device 100 comprises an inspection data generating circuit 3, a syndrome generating circuit 4, and an error bit selector generating circuit 5. A syndrome signal processing circuit is composed of the inspection data generating circuit 3, the syndrome generating circuit 4, and the error bit selector generating circuit 5.

The inspection data generating circuit 3 generates inspection data for error correction in response to externally written input data. The inspection data is composed of, for example, 9-bit data. Further, the inspection data is composed of, for example, 1-bit error-correctible humming codes.

The syndrome generating circuit 4 detects bit errors in read data on the basis of inspection data read from the input data memory array 2, the read data being obtained by reading data stored in the memory cell array 1. The syndrome generating circuit 4 generates a syndrome signal representative of this bit error. The syndrome signal is composed of, for example, 7-bit data.

The error bit selector generating circuit 5 generates an error bit selector signal of 128-bit from the syndrome signal generated by the syndrome generating circuit 4. Of the 128 bits of this error bit select signal, bits corresponding to error bits indicated by the syndrome signal become high-level, while the remaining bits become low-level.

Furthermore, the semiconductor storage device 100 comprises an error correcting circuit, an internal error I/O address generating circuit 6, and an internal error flag generating circuit 7.

The error correcting circuit is composed of a transfer gate 16, an inverter circuit 17, and a transfer gate 18. The error correcting circuit corrects errors in data read from the memory cell array 1 using the error bit select signal generated on the basis of a syndrome signal.

On the basis of the syndrome signal generated by the syndrome generating circuit 4, the internal error I/O address generating circuit 6 generates an internal error I/O address signal representative of a memory cell in the memory cell array 1 in which a bit error has occurred. This internal error address signal is composed of, for example, 7-bit data and can identify those bits of data read from the memory cell array 1, composed of 128 bits, in which errors have occurred.

On the basis of the syndrome signal generated by the syndrome generating circuit 4, the internal error flag generating circuit 7 generates an internal error flag indicating whether or not there are any error bits in data read from the memory cell array 1. This internal error flag is composed of, for example, a 1-bit flag. It becomes high-level if there are any error bits, whereas it becomes low-level if there are no error bits.

The internal I/O address generating circuit 6 and the internal error flag generating circuit 7 are activated when an internal error monitor enable signal (EME) is inputted from an input pin 12 becomes high-level.

Furthermore, the semiconductor storage device 100 comprises an input pin 8, an input pin 9, an I/O pin 10, an output pin 11, the input pin 12, and an output pin 13.

An address (A0-12) specifying a data storage location is inputted to the input pin 8. This address is composed of, for example, 13-bit data.

A clock (CK) and a control signal are inputted to the input pin 9. The control signal includes, for example, a chip enable signal (CEN), a write enable signal (WEN), and an output enable signal (OEN).

Input data (I0-127) to be written in the semiconductor storage device 100 is inputted to the I/O pin 10. Output data (O0-127) is outputted by the semiconductor storage device 100.

The internal error monitor enable signal (EME) is inputted to the input pin 12 to activate the internal error I/O address generating circuit 6 and the internal error flag generating circuit 7. The internal error monitor enable signal (EME) is, for example, inputted directly by a user. Alternatively, it may be inputted by a peripheral circuit of the semiconductor storage device 100 or a host to which the semiconductor storage device 100 is connected.

The internal error flag generated by the internal error flag generating circuit 7 is outputted from the output pin 13.

Signals inputted to the input pins 8, 9, and 12 are inputted by, for example, a circuit integrated on the same chip. Alternatively, they may be inputted by the host to which the semiconductor storage device 100 is connected.

Now, description will be given of operations of the semiconductor storage device 100 configured as described above.

When a high-level write enable signal (WEN) is inputted to the input pin 9, the semiconductor storage device 100 executes a data write process. When input data to be written in the semiconductor storage device 100 is inputted from the I/O pin 10, it is inputted to an input buffer 14. The input buffer 14 outputs 128-bit input data (DIN0-127) on the basis of a control signal inputted from the input pin 9. The input data (DIN0-127) outputted by the input buffer 14 is written in the memory cell array 1. The input data (DIN0-127) is also inputted to the inspection data generating circuit 3. On the basis of the input data (DIN0-127), the inspection data generating circuit 3 generates inspection data composed of 9-bit humming codes. The inspection data is written in the inspection data memory cell array 2.

An address (A0-12) is inputted to the input pin. The address (A0-12) is inputted to each of the memory cell array 1 and the inspection data memory cell array 2. The memory cell array 1 stores input data (DIN0-127) at locations specified by the address (A0-12). Similarly, the inspection data memory cell array 2 stores inspection data at locations specified by the address (A0-12).

On the other hand, the semiconductor storage device 100 executes a data read process when a high-level OEN and a low-level WEN are input to the input pin 9.

Data (DOUT0-127) read from the memory cell array 1 is inputted to each of the transfer gate 16 and the inverter circuit 17. The inverter circuit 17 outputs the input data after inverting it. The data outputted by the inverter circuit 17 is inputted to the transfer gate 18.

Furthermore, the data (DOUT0-127) read from the memory cell array 1 and inspection data read from the inspection data memory cell array 2 are inputted to the syndrome generating circuit 4. The syndrome generating circuit 4 generates a syndrome signal (SY0-6). The syndrome signal (SY0-6) is inputted to each of the error bit selector generating circuit 5, the internal error I/O address generating circuit 6, and the internal error flag generating circuit 7.

The error bit selector generating circuit 5 generates an error bit selector signal of 128-bit. This error bit selector signal is inputted to a control terminal of the transfer gate 16 and to a control terminal of the transfer gate 18.

The transfer gate 16 outputs inputted data (DOUT0-127) in accordance with the error bit selector signal inputted to its control terminal. The transfer gate 16 outputs the input data if the error bit selector signal is low-level.

The transfer gate 18 outputs input data in accordance with an error bit selector signal inputted to its control terminal. The transfer gate 18 outputs the input data if the error bit selector signal is high-level.

Specifically, bits in which no errors are occurring travel through a path “A” passing through the transfer gate 16. On the other hand, bits in which errors are occurring travel through a path “B” passing through the transfer gate 18. In this manner, error bits are corrected.

Data having its errors corrected by the transfer gates 16 and 18 is inputted to an output buffer 15. The output buffer 15 outputs output data of 128-bit (O0-127) on the basis of a control signal inputted from the input pin 9. The output data (O0-127) is externally outputted from the I/O pin 10.

The internal error I/O address generating circuit 6 generates the internal error I/O address signal on the basis of an inputted syndrome signal (SY0-6) if an internal error monitor enable signal (EME) is inputted. This internal error I/O address signal is externally outputted from the output pin 11.

The internal error flag generating circuit 7 generates the internal error flag on the basis of an inputted syndrome signal (SY0-6) if an internal error monitor enable signal (EME) is inputted. This internal error flag is externally outputted from the output pin 13.

Now, description will be given of an evaluation method for the semiconductor storage device 100 shown in FIG. 1.

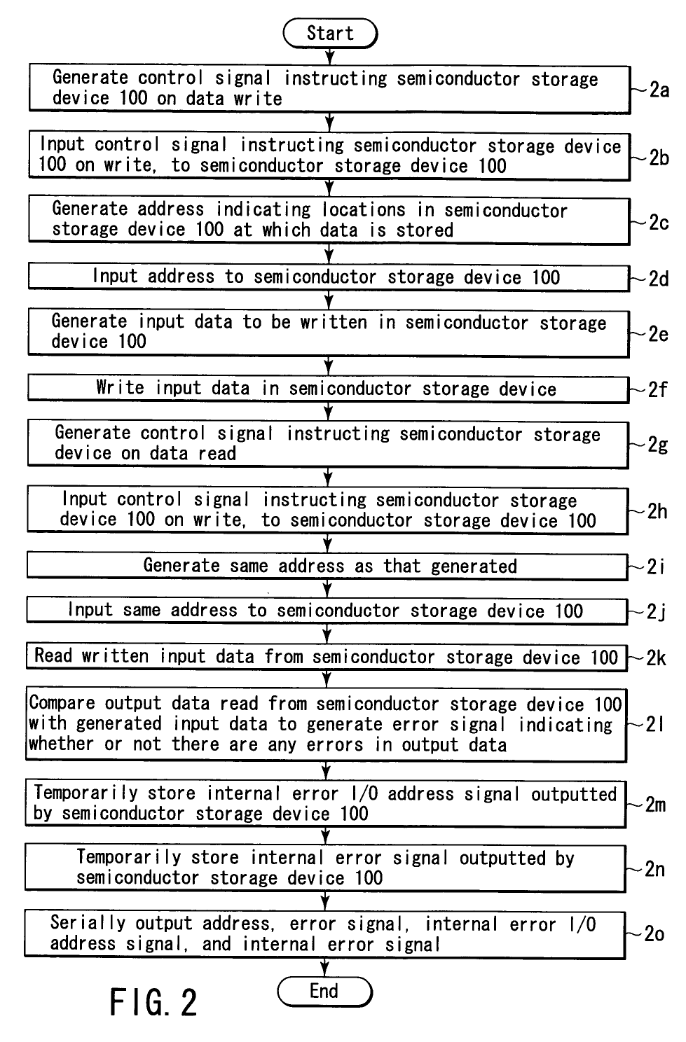

FIG. 2 is a flow chart representing an evaluation method for the semiconductor storage device 100, shown in FIG. 1. In this case, for example, evaluation is carried out by a host memory tester to which the semiconductor storage device 100 is connected. However, the present invention is not limited to this aspect. The evaluation may be carried out by a BIST (Built-In Self Testing) circuit integrated on the same chip on which the semiconductor storage device 100 is formed.

In step 2a, the host memory tester generates a control signal that instructs the semiconductor storage device 100 on a data write. Then, the host memory tester shifts from step 2a to step 2b to input the control signal instructing the semiconductor storage device 100 on the write, to the semiconductor storage device 100.

Then, the host memory tester shifts from step 2b to step 2c to generate the address specifying a location in the semiconductor storage device 100 at which the data is stored. Then, the host memory tester shifts from step 2c to step 2d to input the address to the semiconductor storage device 100.

Then, the host memory tester shifts from step 2d to step 2e to generate input data to be written in the semiconductor storage device 100. Then, the host memory tester shifts from step 2e to 2f to write the data in the semiconductor storage device 100.

Then, the host memory tester shifts from the step 2f to step 2g to generate a control signal that instructs Then, the host memory tester shifts from step 2g to 2h to input the control signal instructing the semiconductor storage device 100 on the read, to the semiconductor storage device 100.

Then, the host memory tester shifts from the step 2h to 2i to generate the same address as that generated. Then, the host memory tester shifts from step 2i to step 2j to input the same address to the semiconductor storage device 100.

Then, the host memory tester shifts from step 2j to step 2k to read the written input data from the semiconductor storage device 100. Then, the host memory tester shifts from step 2k to step 2l to compare the output data read from the semiconductor storage device 100 with the generated input data to generate an error signal indicating whether or not there are any errors in the output data.

Then, the host memory tester shifts from step 2l to step 2m to store temporarily the internal error I/O address signal outputted by the semiconductor storage device 100. Then, the host memory tester shifts from step 2m to step 2n to store temporarily the internal error signal outputted by the semiconductor storage device 100.

Then, the host memory tester shifts from step 2n to 2o to output externally serially the address, the error signal, the internal error I/O address signal, and the internal error signal.

As described above, in the first embodiment, the write data is stored in the memory cell array 1. Further, the inspection data required to correct errors in the write data is stored in the inspection memory cell array 1.

On the other hand, the syndrome signal is generated from data read from the memory cell array 1 and the inspection data read from the inspection data memory cell array 2. Then, on the basis of the syndrome signal, errors in the read data are corrected. Then, the data having its errors corrected is externally outputted. Further, simultaneously, on the basis of the syndrome signal, the internal error flag indicating whether or not there are any error bits in the data having its errors not corrected yet and the internal error I/O address signal identifying the addresses of error bits are generated and externally outputted.

Thus, according to the first embodiment, data having its errors corrected is externally outputted, so that operations of the semiconductor storage device 100 after error correction can be evaluated. Further, the internal error flag and the internal error I/O address signal allow the evaluation of operations of the memory cell array before the error correction. Thus, operation tests before and after error correction are simultaneously carried out to enable test time to be reduced. Furthermore, test costs can be reduced.

Moreover, if the internal error monitor enable signal (EME) is inputted to the semiconductor storage device 100, the internal error I/O address signal and the internal error flag are outputted. Consequently, the user can select the type of test.

Further, the internal error I/O address signal enable the identification of addresses of memory cells in the memory cell array 1 in which error bits have occurred. Bit errors resulting from the destruction of cell data may be caused by software errors. However, this probability is very low. Furthermore, when tests are carried out in an environment that can prevent cell data from being destroyed by software errors, it is possible to identify defective memory cells in the memory cell array 1.

In the first embodiment, data written in the semiconductor storage device 100 and the inspection data are stored in the separate memory cell arrays. However, the present invention is not limited to this aspect. The inspection data memory cell array 2 may be contained in the memory cell array 1.

### SECOND EMBODIMENT

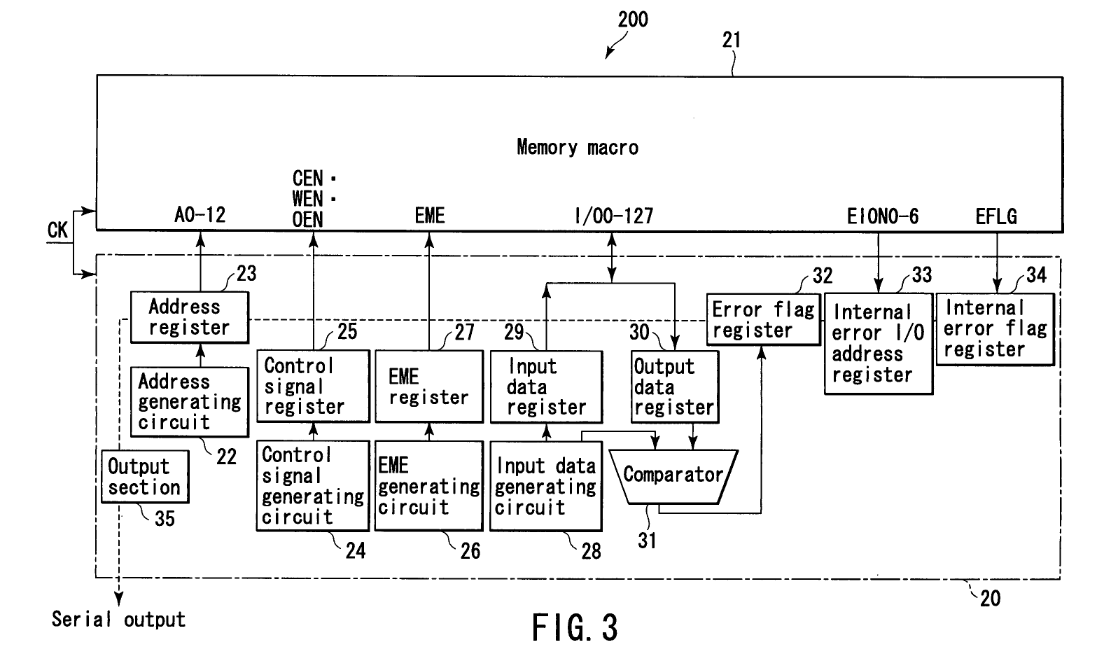

FIG. 3 is a block diagram of a semiconductor storage device 200 according to a second embodiment of the present invention.

The semiconductor storage device 200 includes a memory macro 21 composed of the semiconductor storage device 100, shown in the first embodiment, and a BIST (Built-In Self Testing) circuit 20 that is a memory self test circuit for testing the memory macro 21. The configuration and operation of the memory macro 21 are similar to those in the first embodiment.

A clock (CK) generated by, for example, a peripheral circuit of the semiconductor storage device 200 is inputted to each of the memory macro 21 and the BIST circuit 20. The memory macro 21 and the BIST circuit 20 operate on the basis of this clock (CK).

The BIST circuit 20 comprises an address generating circuit 22, an address register 23, a control signal generating circuit 24, a control signal register 25, an EME generating circuit 26, and an EME register 27.

The address generating circuit 22 generates an address (A0-12) used to specify those locations in the memory cell array 1 in the memory macro 21 at which data is stored. This address is composed of, for example, 13-bit data. The address register 23 temporarily stores the address (A0-12) generated by the address generating circuit 22.

The control signal generating circuit 24 generates control signals required to write or read data in or from the memory macro 21. These control signals include, for example, a chip enable signal (CEN), a write enable signal (WEN), and an output enable signal (OEN). The control signal register 25 temporarily stores the control signals generated by the control signal generating circuit 24.

The EME generating circuit 26 generates an internal error monitor enable signal (EME) used to activate the internal error I/O address generating circuit 6 and internal error flag generating circuit 7, provided in the memory macro 21. The EME register 27 temporarily stores an internal error monitor enable signal (EME) generated by the EME generating circuit 26.

Further, BIST circuit 20 comprises an input data generating circuit 28, an input data register 29, an output data register 30, a comparator 31, and an error flag register 32.

The input data generating circuit 28 generates arbitrary input data (I0-127) composed of 128 bits. The input data register 29 temporarily stores the input data (I0-127) generated by the input data generating circuit 28.

The output data register 30 temporarily stores output data (O0-127) outputted by the memory macro 21 and having its errors corrected.

The comparator 31 compares the input data (I0-127) inputted by the input data generating circuit 28 with the output data (O0-127) inputted by the output data register 30. The comparison results are outputted as an error flag.

The error flag register 32 temporarily stores the error flag outputted by the comparator 31.

Further, the BIST circuit 20 comprises an internal error I/O address register 33, an internal error flag register 34, and an output section 35.

The internal error I/O address register 33 temporarily stores the internal error I/O address signal outputted by the memory macro 21. The internal error flag register 34 temporarily stores the internal error flag outputted by the memory macro 21.

The output section 35 externally serially outputs the error flag, the internal error I/O address signal, and the internal error flag. That is, the address register 23, the error flag register 32, the internal error I/O address register 33, and the internal error flag register 34 are chained together to output serially data stored in the registers. The data is, for example, outputted directly to the user. Alternately, it may be outputted to a peripheral circuit of the semiconductor storage device 200 or a host to which the semiconductor storage device 200 is connected. Furthermore, the output method is not limited to the serial output. Output sections may be provided for the respective data stored in the corresponding registers.

Description will be given of operations of the semiconductor storage device 200.

First, description will be given of an operation of writing data in the memory macro 21.

The control signal generating circuit 24 generates both the chip enable signal (CEN) and the high-level write enable signal (WEN). The chip enable signal (CEN) and the write enable signal (WEN) are held by the control signal register 25. The control signal register 25 outputs the chip enable signal (CEN) and the write enable signal (WEN) while synchronizing with the clock (CK). The chip enable signal (CEN) and write enable signal (WEN) outputted by the control signal register 25 are inputted to the memory macro 21. Then, the memory macro 21 executes a data write process.

The address generating circuit 22 generates the address (A0-12) used to specify locations in the memory cell array 1 in the memory macro 21 at which data is stored. The address (A0-12) is stored in the address register 23. The address register 23 outputs the address (A0-12) while synchronizing with the clock (CK). The address (A0-12) outputted by the address register 23 is inputted to the memory macro 21.

The input data generating circuit 28 generates arbitrary input data (I0-127). The input data register 29 holds the input data (I0-127) generated by the input data generating circuit 28. The input data (I0-127) outputted by the input data register 29 is inputted to the memory macro 21.

Then, the memory macro 21 stores the input data (I0-127) at the locations specified by the address (A0-12) inputted by the address register 23.

Now, description will be given of an operation of reading data from the memory macro 21.

The control signal generating circuit 24 generates the chip enable signal (CEN), the high-level output enable signal (OEN), and the low-level write enable signal (WEN). The control signal register 25 holds the chip enable signal (CEN), the output enable signal (OEN), and the write enable signal (WEN). The control signal register 25 outputs these control signals while synchronizing with the clock (CK). The chip enable signal (CEN), output enable signal (OEN), and write enable signal (WEN) outputted by the control signal register 25 are inputted to the memory macro 21. Then, the memory macro 21 executes a data read process.

The address generating circuit 22 generates the same address (A0-12) as that (A0-12) generated upon the write. The address (A0-12) is held by the address register 23. The address register 23 outputs the address (A0-12) while synchronizing with the clock (CK). The address (A0-12) outputted by the address register 23 is inputted to the memory macro 21. Then, the memory macro 21 executes a process of outputting stored data specified by the address (A0-12).

The EME generating circuit 26 generates the internal error monitor enable signal (EME), described above. The EME signal is held by the EME register 27. The EME register 27 outputs the EME signal while synchronizing with the clock (CK). The EME signal outputted by the EME register 27 is inputted to the memory macro 21. The memory macro 21 activates the internal error I/O address generating circuit 6 and the internal error flag generating circuit 7.

The output data register 30 stores data outputted by the memory macro 21 and having its errors corrected. The output data (O0-127) stored in the output data register 30 is inputted to the comparator 31. Further, input data (I0-127) generated by the input data generating circuit 28 as described above is inputted to the comparator 31.

The comparator 31 compares the input data (I0-127) with the output data (O0-127). The comparator 31 then generates the error flag indicating whether or not there are any errors in the output data (O0-127). This error flag is composed of, for example, 1-bit flag that is high-level if there are any errors and is low-level if there are no errors. The error flag outputted by the comparator 31 is stored in the error flag register 32.

The internal error I/O address signal outputted by the memory macro 21 is stored in the internal error I/O address register 33. Further, the internal error flag outputted by the memory macro 21 is stored in the internal error flag register 34.

Then, the output section 35 serially outputs the address (A0-12), the error flag, the internal error I/O address signal, and the internal error flag.

Now, description will be given of an evaluation method for the memory macro 21, shown in FIG. 3.

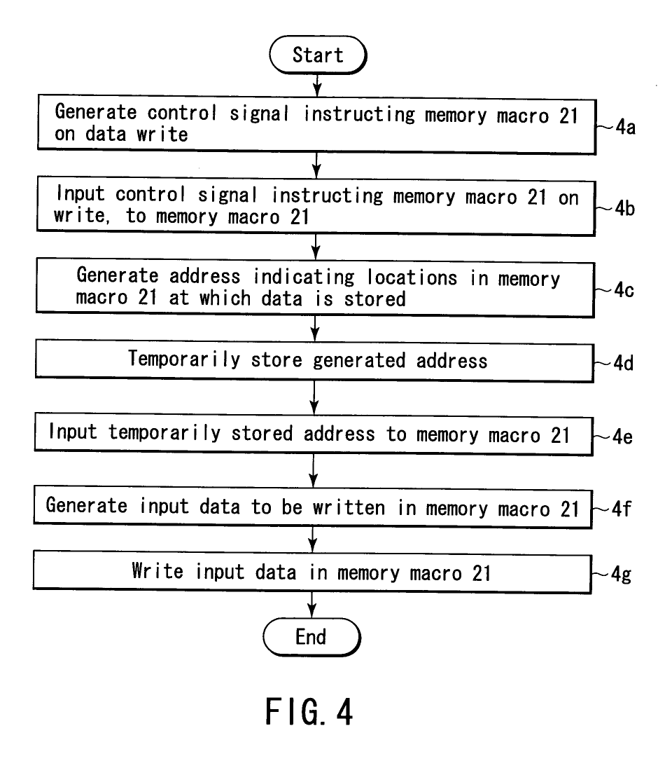

First, description will be given of a process in which the BIST circuit writes data to the memory macro 21. FIG. 4 is a flow chart representing the process in which the BIST circuit 20 writes data in the memory macro 21.

In step 2a, the BIST circuit 20 generates the control signal instructing the memory macro 21 on a data write. Then, the BIST circuit 20 shifts from step 4a to step 4b to input the control signal instructing the memory macro 21 on the data write, to the memory macro 21.

Then, the BIST circuit 20 shifts from step 4b to step 4c to generate the address specifying locations in the memory macro 21 at which data is stored. Then, the BIST circuit 20 shifts from step 4c to step 4d to store temporarily the generated address. Then, the BIST circuit 20 shifts from step 4d to step 4e to input the temporarily stored address to the memory macro 21.

Then, the BIST circuit 20 shifts from step 4e to step 4f to generate the input data to be written in the memory macro 21. Then, the BIST circuit 20 shifts from step 4f to step 4g to write the input data to the memory macro 21.

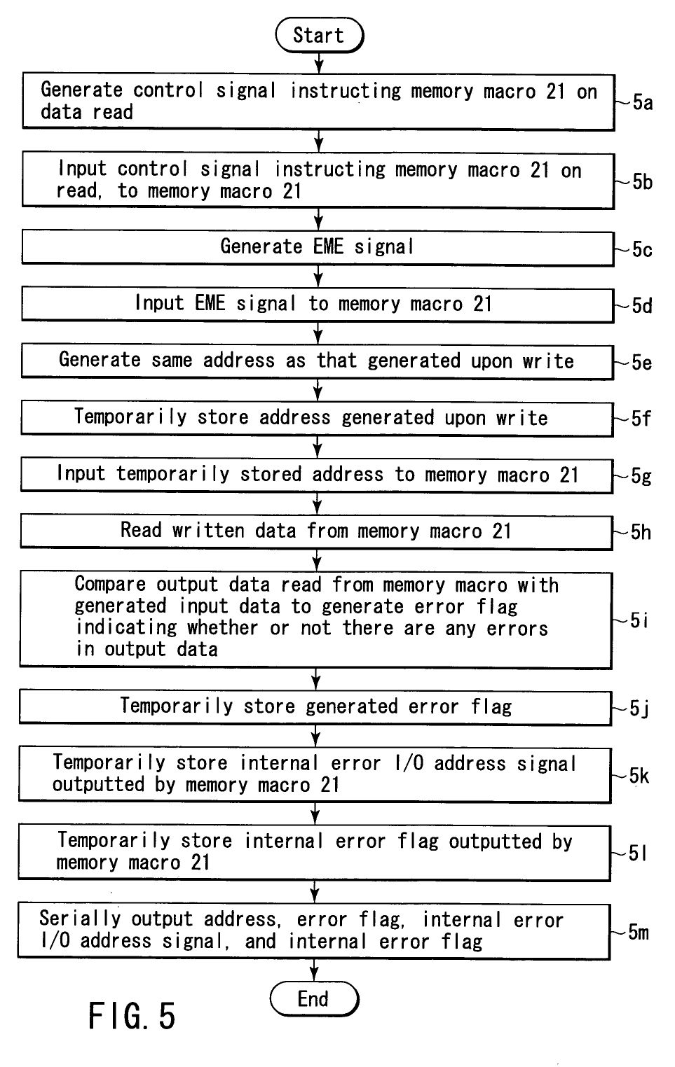

Now, description will be given of a process in which the BIST circuit 20 reads data from the memory macro 21. FIG. 5 is a flow chart representing the process in which the BIST circuit 20 reads data from the memory macro 21.

In step 5a, the BIST circuit generates a control signal instructing the memory macro 21 on a data read. Then, the BIST circuit 20 shifts from step 5a to step 5b to input the control signal instructing the memory macro 21 on the read, to the memory macro 21.

Then, the BIST circuit 20 shifts from step 5b to step 5c to generate the EME signal, described above. Then, the BIST circuit 20 shifts from step 5c to 5d to input the EME signal to the memory macro 21.

Then, the BIST circuit 20 shifts from step 5d to step 5e to generate the same address as that generated. Then, the BIST circuit 20 shifts from step 5e to step 5f to store temporarily the same address. Then, the BIST circuit 20 shifts from step 5f to step 5g to input the temporarily stored address to the memory macro 21.

Then, the BIST circuit 20 shifts from step 5g to step 5h to read input data written as described above, from the memory macro 21.

Then, the BIST circuit 20 shifts from step 5h to step 5i to compare the output data read from the memory macro 21 with input data generated as described above to generate the error flag indicating whether or not there any errors in the output data. Then, the BIST circuit 20 shifts from step 5i to step 5j to store temporarily the generated error flag.

Then, the BIST circuit 20 shifts from step 5j to step 5k to store temporarily the internal error I/O address signal outputted by the memory macro 21 and indicating error addresses in the output data which has not yet had its errors corrected by the memory macro 21.

Then, the BIST circuit 20 shifts from step 5k to step 51 to store temporarily the internal error flag outputted by the memory macro 21 and indicating whether or not there are any errors in the output data which has not yet had its errors corrected by the memory macro 21.

Then, the BIST circuit 20 shifts from step 51 to step 5m to output externally serially the address, the error flag, the internal error I/O address signal, and the internal error flag.

As described above in detail, in the second embodiment, the address and input data are generated and inputted to the memory macro 21. Then, the input data is written at locations specified by the address. On the other hand, output data having its errors corrected by the memory macro 21 is read from the memory macro 21. Then, the input data is compared with the output data to generate the error flag indicating whether or not there are any errors in the output data. Then, the semiconductor storage device 200 externally serially outputs the address, the error flag, the internal error I/O address signal outputted by the memory macro 21, and the internal error flag outputted by the memory macro 21.

Thus, according to the second embodiment, the serially outputted data enables evaluation as to whether or not there are any errors in output data outputted by the memory macro 21. It is also possible to carry out evaluation as to whether or not there are any error bits in data read from the memory cell array 1.

Furthermore, if there are any bit errors, it is possible to identify the addresses of those memory cells in the memory cell array 1 in which error bits have occurred. Thus, the use can evaluate the manufacturing yield of the memory macro 21 and the processing yield of the memory cell array 1 through a single measurement.

This enables test time to be reduced, thus reducing test costs.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor storage device comprising:
a memory cell array which stores externally inputted normal data;
an inspection data generating circuit which generates inspection data corresponding to the normal data;
an inspection storing section which stores the inspection data;
a syndrome generating circuit which detects bit errors in read data on the basis of the inspection data and which generates a syndrome signal corresponding to the bit errors, the read data being obtained by reading the normal data stored in the memory cell array; and
a syndrome signal processing circuit which corrects the bit errors in the read data on the basis of the syndrome signal and which generates an internal error address signal representative of addresses of memory cells in the memory cell array in which the bit errors have occurred.

2. The semiconductor storage device according to claim 1, wherein the syndrome signal processing circuit further comprises a circuit which generates, on the basis of the syndrome signal, an internal error signal indicating whether or not there are any errors in the read data.

3. The semiconductor storage device according to claim 2, further comprising a first input section to which an error monitor signal indicating that monitoring of possible errors is to be started is inputted, and
wherein the syndrome signal processing circuit generates the internal error address signal and the internal error signal if the error monitor signal is inputted to the input section.

4. The semiconductor storage device according to claim 2, further comprising a first output section which externally outputs corrected data obtained by correcting error bits in the read data;
a second output section which externally outputs the internal error address signal; and
a third output section which externally outputs the internal error signal.

5. The semiconductor storage device according to claim 1, wherein the inspection data is composed of humming codes.

6. A semiconductor storage device comprising:
a memory macro having a memory cell array and an error correcting circuit;
an input data generating circuit which generates input data to be written in the memory macro;
an error signal generating circuit which compares output data read from the memory macro with the input data generated by the input data generating circuit to generate an error signal indicating whether or not there are any errors in the output data based on a comparison result of the output data and the input data; and
an internal error address register which temporarily stores an internal error address signal outputted by the memory macro and representing error addresses of memory cells in the memory cell array in which bit errors in read data has occurred, the read data being obtained by reading the input data stored in the memory cell array.

7. The semiconductor storage device according to claim 6, further comprising an internal signal register which temporarily stores an internal error signal outputted by the memory macro and indicating whether or not there are any errors in the read data.

8. The semiconductor storage device according to claim 7, further comprising an error monitor signal generating circuit which generates an error monitor signal indicating that monitoring of possible errors is to be started, and
wherein the memory macro outputs the internal error address signal and the internal error signal if the error monitor signal is inputted.

9. The semiconductor storage device according to claim 7, further comprising an address generating circuit which generates an address used to specify locations in the memory macro at which the input data is stored.

10. The semiconductor storage device according to claim 9, further comprising an error signal register which temporarily stores the error signal; and
an address register which temporarily stores the address.

11. The semiconductor storage device according to claim 10, further comprising an output section which externally serially outputs the address, the error signal, the error address signal, and the internal error signal.

12. An evaluation method for a semiconductor storage device having a memory cell array and an error correcting circuit, the method comprising:
generating an address used to specify locations in the semiconductor storage device at which input data is stored;
temporarily storing the address;
inputting the temporarily stored address to the semiconductor storage device;
generating the input data to be written in the semiconductor storage device;
writing the input data in the semiconductor storage device;
reading the input data from the semiconductor storage device;
comparing the output data read from the semiconductor storage device with the generating input data to generate an error signal indicating whether or not there are any errors in the output data based on a comparison result of the output data and the input data;
temporarily storing the error signal; and
temporarily storing an internal error address signal outputted by the semiconductor storage device and representing error addresses of memory cells in the memory cell array in which bit errors in read data have occurred, the read data being obtained by reading the input data stored in the memory cell array.

13. The evaluation method for a semiconductor storage device according to claim 12, further comprising, after temporarily storing the error address signal, temporarily storing an internal error signal outputted by the semiconductor storage device and indicating whether or not there are any errors in the read data obtained by reading the input data stored in the memory cell array.

14. The evaluation method for a semiconductor storage device according to claim 13, further comprising, after temporarily storing the internal error signal, serially outputting the address, the error signal, the internal error address signal, and the internal error signal.
